(19) United States
(12) Patent Application Publication
(10) Pub. No.: US 2011/0233509 A1
(43) Pub. Date: Sep. 29, 2011

(54) NONVOLATILE MEMORY DEVICE

(75) Inventors: Takashi SHIGEOKA, Kanagawa (JP); Tetsuji Kunitake, Mie (JP); Hisashi Kato, Mie (JP); Kenji Aoyama, Kanagawa (JP); Kensuke Takahashi, Kanagawa (JP)

(73) Assignee: Kabushiki Kaisha Toshiba, Tokyo (JP)

(21) Appl. No.: 13/052,179

(22) Filed: Mar. 21, 2011

(30) Foreign Application Priority Data
Mar. 24, 2010 (JP) 2010-068599

(51) Int. Cl. H01L 45/00

(52) U.S. Cl. 257/4; 257/E45.003

(57) ABSTRACT

According to one embodiment, a nonvolatile memory device including a nonvolatile memory layer is provided. The nonvolatile memory layer is formed of a metal oxide film that includes an element with a higher electronegativity compared with a metal element forming the metal oxide film in the metal oxide film at a concentration of 25 at % or less.

### CROSS-REFERENCE TO RELATED APPLICATIONS

This application is based upon and claims the benefit of priority from the prior Japanese Patent Application No. 2010-68599, filed on Mar. 24, 2010; the entire contents of which are incorporated herein by reference.

### FIELD

Embodiments described herein relate generally to nonvolatile memory device.

### BACKGROUND

Recently, as a nonvolatile memory device, a ReRAM (Resistive Random Access Memory) attracts attention, which stores therein resistance value information on a variable resistive element that is electrically alterable, for example, a high resistance state and a low resistance state in a nonvolatile manner. Such a ReRAM is, for example, configured such that variable resistance memory cells in each of which a variable resistive element as a memory element and a rectifier element such as a diode are connected in series are arranged in an array at intersection portions of a plurality of bit lines that extend in parallel with a first direction and a plurality of word lines that extend in parallel with a second direction vertical to the first direction (for example, see Japanese Patent Application Laid-open No. 2009-99200).

The variable resistive element is configured such that a dielectric thin film formed of metal oxide is sandwiched by two metal electrodes, and is an element capable of changing from a high resistance state to a low resistance state or from a low resistance state to a high resistance state by applying voltage or current between the metal electrodes. The variable resistive element stores therein this reversible resistance value information as data. A process of changing from the high resistance state to the low resistance state is called a set process and a process of changing from the low resistance state to the high resistance state is called a reset process.

Such a variable resistance memory has a unipolar type capable of performing both the set process and the reset process by applying current or voltage in one direction and a bipolar type in which the application direction of current or voltage is opposite between the set process and the reset process. The unipolar type is often used for one in which binary transition-metal oxide composed of two elements of transition metal and oxygen is used and the bipolar type is often used for one in which ternary or more oxide composed of three or more elements including oxygen is used (for example, see, Akihito SAWA, “Nonvolatile resistance-switching memory in transition-metal oxides (ReRAM)”, On BUTURI, Vol. 75, No. 9, p. 1109 (2006)).

The unipolar type causes the variable resistive element to transition to the high resistance reset state in the reset process, for example, by applying voltage lower than in the set process for a period of time longer than in the set process. At this time, current for the reset process flows with a driver of the variable resistance memory, current/voltage source circuits, a parasitic capacitance of wires, and the selected variable resistance memory as load resistances. In the set state before the reset process, the variable resistive element is in the low resistance state, so that large current flows therein, however, in the reset process, the variable resistive element transitions to the high resistance state, so that voltage between both ends of the variable resistive element rises instantaneously in relation to other load resistances. At this time, if the voltage between both ends of the variable resistive element exceeds a set voltage, a problem may occur in that the variable resistive element transitions to the low resistance set state again and the reset process cannot be performed (for example, see Japanese Patent Application Laid-open No. 2009-157982).

### BRIEF DESCRIPTION OF THE DRAWINGS

FIG. 1 is a diagram illustrating an example of a memory cell array configuration of a nonvolatile memory device according to embodiments;

FIG. 2 is a cross-sectional view schematically illustrating an example of a structure of a nonvolatile memory device according to a first embodiment;

FIG. 3A to FIG. 3C are diagrams schematically illustrating a model of a transition state between a high resistance state and a low resistance state in a variable resistive element;

FIG. 4A and FIG. 4B are graphs illustrating typical current-voltage characteristics of variable resistance memories;

FIG. 5 is a graph explaining an erroneous setting problem;

FIG. 6 is a graph schematically illustrating dependency of a voltage margin on the number of switching;

FIG. 7 is a graph illustrating an example of a relationship between concentration of an element with a high electronegativity and a voltage margin;

FIG. 8A to FIG. 8H are cross-sectional views schematically illustrating an example of a procedure of a manufacturing method of the nonvolatile memory device according to the first embodiment; and

FIG. 9A to FIG. 9D are cross-sectional views schematically illustrating an example of a procedure of a manufacturing method of a nonvolatile memory device according to a second embodiment.

### DETAILED DESCRIPTION

In general, according to one embodiment, a nonvolatile memory device including a nonvolatile memory layer is provided. The nonvolatile memory layer is formed of a metal oxide film that includes an element with a higher electronegativity compared with a metal element forming the metal oxide film in the metal oxide film at a concentration of 25 at % or less.

A nonvolatile memory device according to the embodiments will be explained below in detail with reference to the accompanying drawings. The present invention is not limited to these embodiments. Moreover, cross-sectional views of the nonvolatile memory device used in the following embodiments are schematic ones and a relation between the thickness and the width of a layer, the ratio of the thicknesses of the respective layers, and the like may be different from realistic ones. Furthermore, the film thickness illustrated below is an example and is not limited to this.

### First Embodiment

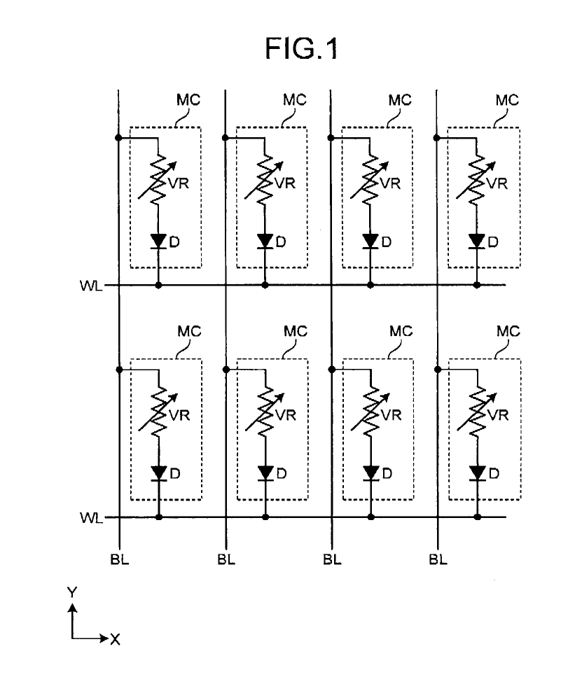

FIG. 1 is a diagram illustrating an example of a memory cell array configuration of a nonvolatile memory device according to embodiments. In FIG. 1, a right and left direction in the drawing is an X direction and a direction vertical to the X direction in the drawing is a Y direction. A plurality of word lines WL that extend in the X direction (row direction) and a plurality of bit lines BL that extend in the Y direction (column direction) at a height different from the word lines WL are arranged to intersect with each other and a resistance change memory cell (hereinafter, also called simply, a memory cell) MC in which a variable resistive element VR and a rectifier element D are connected in series is arranged at each intersection portion. In this example, the variable resistive element VR is connected to the bit line BL at one end and is connected to the word line WL at the other end via the rectifier element D. In the first embodiment, explanation is given for the case of an unipolar type nonvolatile memory device as an example.

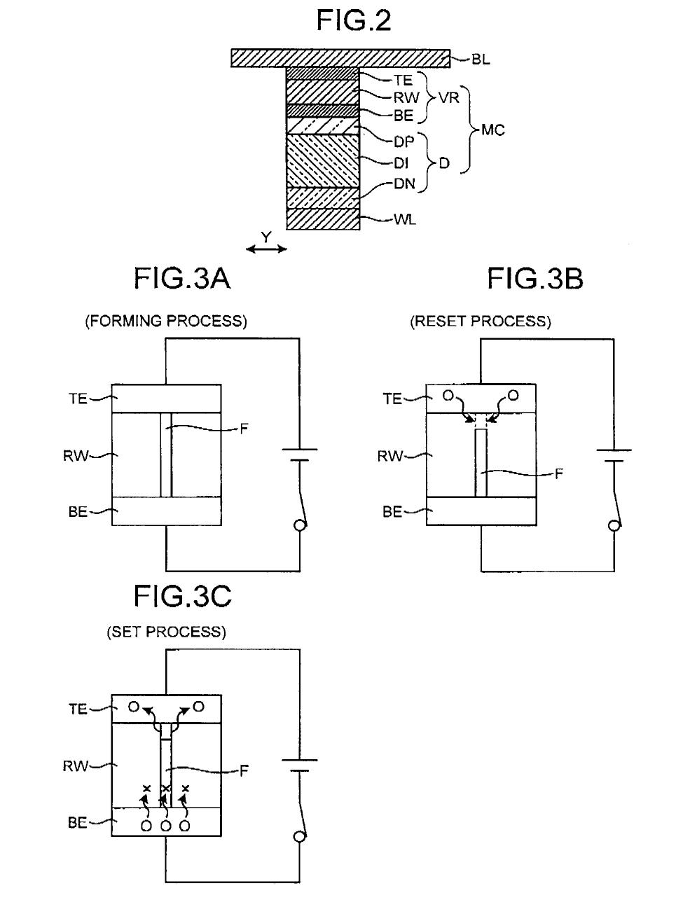

FIG. 2 is a cross-sectional view schematically illustrating an example of a structure of a nonvolatile memory device according to the first embodiment. FIG. 2, for example, illustrates a state of a portion of a cross section on the bit line BL along the Y direction in FIG. 1. On the word line WL that extends in the X direction, the rectifier element D and the variable resistive element VR forming the memory cell MC are stacked and the bit line BL that extends in the Y direction is formed on the variable resistive element VR.

The rectifier element D is formed of a material having a rectification such as a Schottky diode, a PN junction diode, and a PIN diode and is formed on the word line WL. In the present embodiment, the case is illustrated as an example in which the rectifier element D is formed of a polysilicon layer having a PIN structure formed by stacking an N-type polysilicon film DN with the thickness of about 20 nm, an I-type polysilicon film DI with the thickness of about 110 nm, and a P-type polysilicon film DP with the thickness of about 20 nm in order from the side of the word line WL. Moreover, in this example, the rectifier element D is arranged so that current flows from the bit line BL to the word line WL.

The variable resistive element VR includes a lower portion electrode layer BE, a variable resistive layer RW as a nonvolatile memory layer, and an upper portion electrode layer TE. The lower portion electrode layer BE and the upper portion electrode layer TE are formed of a metal material or a metal nitride material that does not impair the variable resistivity of the variable resistive layer RW by reacting with the variable resistive layer RW. As such the lower portion electrode layer BE and the upper portion electrode layer TE, for example, it is possible to use at least one metal material selected from Pt, Au, Ag, Ru, Ir, Co, Al, Ti, W, Mo, Ta, and the like or nitride of at least one metal material selected from Ti, W, Mo, Ta, and the like. The upper portion electrode layer TE or the lower portion electrode layer BE can be omitted depending on the case.

The variable resistive layer RW is formed of a thin film obtained by uniformly mixing an element whose electronegativity is higher than a metal element forming a metal oxide film (hereinafter, simply called an element with a high electronegativity) in the metal oxide film capable of switching between a high resistance state and a low resistance state by controlling a voltage value and an application time. As the metal oxide film, for example, a metal oxide film including at least one element of Hf, Zr, Co, Al, Mn, Ti, Ta, and the like can be exemplified. As the element with a high electronegativity, an element such as Si and Al can be exemplified. When being used as the nonvolatile memory device, in the variable resistive layer RW, oxygen deficiency is introduced and a filament that is an electrical conduction path is locally formed.

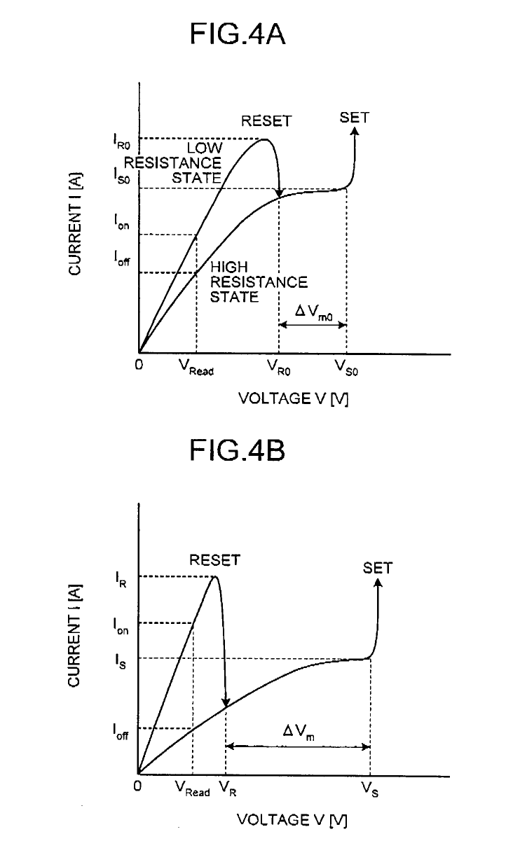

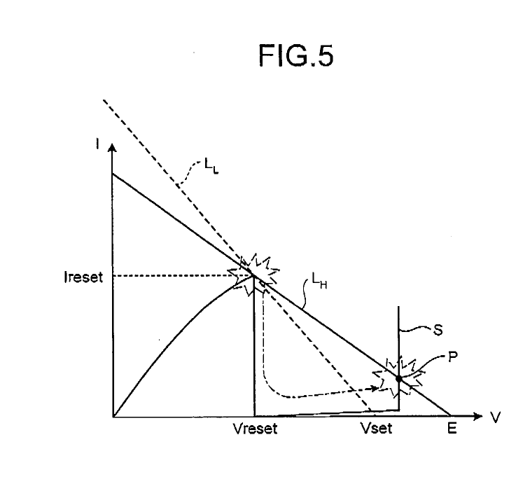

Transition between the high resistance state and the low resistance state in the variable resistance memory is explained below. FIG. 3A to FIG. 3C are diagrams schematically illustrating a model of a transition state between the high resistance state and the low resistance state in the variable resistive element, and FIG. 4A and FIG. 4B are graphs illustrating typical current-voltage characteristics of the variable resistance memories. In FIG. 4A and FIG. 4B, a horizontal axis indicates a voltage V (V) applied to the variable resistive element VR and a vertical axis indicates a current I (A) that flows in the variable resistive element VR. FIG. 4A and FIG. 4B indicates that the larger the tilt of the curve is, the smaller the resistance is.

Typically, immediately after forming the variable resistance memory, the variable resistive layer RW is in an insulating state, so that a forming process of applying a high voltage to the memory cell MC (between the upper portion electrode layer TE and the lower portion electrode layer BE) to lower the resistance is performed. As shown in FIG. 3A, a current path called a filament F is generated in the memory cell MC by the forming process. This filament F is considered to be formed by continuous oxygen deficient regions in the variable resistive layer RW. Therefore, the variable resistive layer RW becomes a low resistance state. The forming process enables the memory cell MC to function as a nonvolatile memory element.

Because the variable resistive layer RW is in the low resistance state after the forming process, a reset process of making the variable resistive layer RW in the high resistance state is performed. In the reset process, as shown by RESET in FIG. 4A, when voltage is applied to the memory cell MC and current reaches a predetermined current amount I_{RO}, the variable resistive layer RW becomes the high resistance state by Joule heat. This is considered to be because oxygen is supplied from an anode, i.e., the upper portion electrode layer TE to the filament F, that is, the filament F is oxidized, as shown in FIG. 3B. The voltage at which the reset process is performed is defined as a reset voltage V_{RO}.

On the other hand, a set process of making the variable resistive layer RW in the low resistance state is performed on the memory cell MC that becomes the high resistance state by the reset process. In the set process, as shown by SET in FIG. 4A, when voltage larger than the reset voltage V_{RO} is applied to the memory cell MC and current reaches a predetermined current amount I_{SO}, the variable resistive layer RW becomes the low resistance state. This is considered to be because the oxygen deficiency occurs in the filament F near the anode, i.e., the upper portion electrode layer TE as shown in FIG. 3C. The voltage at which the set process is performed is defined as a set voltage V_{SO}.

When a read voltage V_{Read} is applied to the memory cell MC on which such a reset process or a set process is performed, the current value that flows in the variable resistive layer RW is different between the high resistance state and the low resistance state. For example, when the current value in the high resistance state (state after the reset process) is defined as I_{off} and the current value in the low resistance state (state after the set process) is defined as Iₒₙ, it is possible to determine whether the memory cell MC is in the high resistance state or the low resistance state by detecting these current values I_{off} and Iₒₙ. In this manner, the resistance value information is stored by generating the high resistance state and the low resistance state by the reset process and the set process and the difference in current that flows in the memory cell MC is detected to cause the memory cell MC to function as a memory.

In FIG. 4A, the difference between the set voltage V_{SO} and the reset voltage V_{RO} of the variable resistive layer RW is a voltage margin, which is indicated as ΔVₘ₀ in FIG. 4A.

FIG. 5 is a graph explaining an erroneous setting problem. In this graph, a horizontal axis indicates voltage and a vertical axis indicates current. When the voltage applied to one memory cell MC is E, the resistance (such as the diode D) other than the variable resistive layer RW is R, the voltage applied to the variable resistive layer RW is V, and the current that flows in the variable resistive layer RW is I, the following equations (1) and (2) are obtained as the load characteristics of a peripheral circuit, a parasitic capacitance of wires and the like, and the like other than the variable resistive layer RW.

E=V+RI (1)

I=(E−V)/R (2)

Straight lines L_{L} and L_{H} in FIG. 5 represent equation (2). The straight line L_{L} indicates the load characteristics other than the variable resistive layer RW in the case where the variable resistive layer RW is in the low resistance state after the set process and the straight line L_{H} indicates the load characteristics other than the variable resistive layer RW in the case where the variable resistive layer RW is in the high resistance state after the reset process. Moreover, a curve S in FIG. 5 indicates I-V characteristics of the variable resistive layer RW, which are illustrated in FIG. 4A. In this example, the case is illustrated in which the straight line L_{H} of the load characteristics other than the variable resistive layer RW after the reset process intersects with the I-V characteristic curve S of the variable resistive layer RW at a point P in a region over a set voltage V.

In such a case, in the reset process of data, Joule heat is generated by current that flows in the variable resistive layer RW, for example, by applying a reset voltage Vᵣₑₛₑₜ lower than the set voltage Vₛₑₜ for a period of time longer than in the set process. At the moment of the reset, because the variable resistive layer RW transitions to the high resistance state, the applied voltage to the variable resistive layer RW rises instantaneously. At this time, if the voltage between both ends of the variable resistive layer RW exceeds the set voltage Vₛₑₜ, the erroneous setting problem occurs in which the variable resistive layer RW becomes the set state again and therefore transitions to the low resistance state and cannot be reset to the high resistance state.

Such an erroneous setting problem can be solved by increasing the voltage margin, i.e., the difference between the set voltage Vₛₑₜ and the reset voltage Vᵣₑₛₑₜ in the I-V characteristic curve S of the variable resistive layer RW as shown in FIG. 5.

In the first embodiment, the element with a high electronegativity is uniformly mixed in a metal oxide film forming the variable resistive layer RW. The electronegativity represents difficulty in releasing of oxygen, and oxygen tends to become difficult to release as the electronegativity of an element becomes higher. Therefore, if the element with a high electronegativity is included in the variable resistive layer RW, in the set process, oxygen is difficult to release (state where activation energy is large) compared with the case where the element with a high electronegativity is not included. Consequently, as shown in FIG. 43, a set voltage V_{S} rises compared with the set voltage V_{SO} in the case of the variable resistive layer RW including no element with a high electronegativity.

On the other hand, in the reset process, it is easy to bind to oxygen (state where activation energy is small) compared with the case where the element with a high electronegativity is not included due to the effect of the element with a high electronegativity. Consequently, a reset voltage V_{R} is lowered compared with the reset voltage V_{RO} in the case of the variable resistive layer RW including no element with a high electronegativity.

Consequently, as shown in FIG. 4A and FIG. 4B, a voltage margin ΔVₘ of the variable resistive layer RW formed of a metal oxide film including the element with a high electronegativity becomes larger than the voltage margin ΔVₘ₀ in the case of including no element with a high electronegativity. In other words, in the first embodiment, the voltage margin ΔVₘ can be increased by using a metal oxide film, in which the element with a high electronegativity is uniformly mixed, for the variable resistive layer RW, thereby enabling to suppress generation of the above described erroneous setting problem.

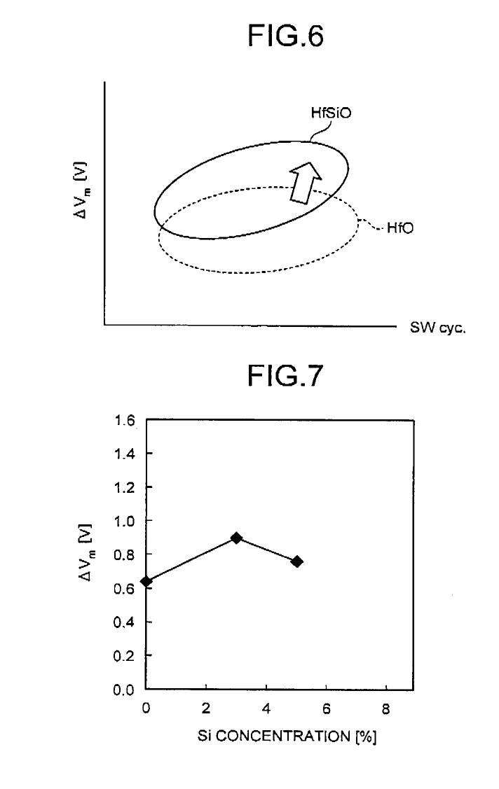

FIG. 6 is a graph schematically illustrating dependency of the voltage margin on the number of switching. In FIG. 6, a horizontal axis indicates the number switching of the variable resistive layer RW and a vertical axis indicates the voltage margin ΔVₘ (V) of the variable resistive layer RW. Moreover, in FIG. 6, the region surrounded by the dotted line indicates typical dependency of the voltage margin on the number of switching in the case of forming the variable resistive layer RW only with an HfO film, and the region surrounded by the solid line indicates typical dependency of the voltage margin on the number of switching in the case of forming the variable resistive layer RW with an HfO film in which Si is uniformly mixed. As shown in FIG. 6, it is found that when the variable resistive layer RW includes the element with a high electronegativity, the voltage margin tends to increase. Moreover, although not shown in FIG. 6, when concentration of Si introduced in the HfO film is increased, switching gradually tends to become difficult, however, increase of the voltage margin ΔVₘ (V) of the variable resistive layer RW is recognized as described above until the Si concentration in the HfO film becomes 25 at %. It is not desirable to include Si at more than 25 at % because switching becomes extremely difficult. In this example, the case of mixing Si in the HfO film is illustrated, however, a similar tendency is obtained again in the case of mixing Si in an oxide film of Zr, Co, Al, Mn, Ti, Ta, or the like. Moreover, a similar tendency is obtained again in the case of mixing Al in an oxide film of Hf, Zr, Mn, Ti, Ta, or the like.

FIG. 7 is a graph illustrating an example of a relationship between concentration of the element with a high electronegativity and the voltage margin. FIG. 7 illustrates the case where an HfO film is used as the variable resistive layer RW and Si is uniformly diffused in the HfO film as the element with a high electronegativity. In FIG. 7, a horizontal axis indicates the Si concentration (at %) in the HfO film and a vertical axis indicates the voltage margin ΔVₘ (V). FIG. 7 illustrates an average of the voltage margin ΔVₘ based on a plurality of experimental results as the voltage margin ΔVₘ.

As shown in FIG. 7, it is found that when Si is mixed in the HfO film at a rate of 3 at % or more and 5 at % or less, the voltage margin ΔVₘ is increased by about 0.15 V to 0.25 V compared with the case of introducing no Si in the HfO film. In other words, introduction of Si in the HfO film at a rate of 3 at % to 5 at % is desirable because the voltage margin ΔVₘ can be increased. FIG. 7 illustrates the case of mixing Si in the HfO film, however, a similar tendency is obtained again in the case of mixing Si in an oxide film of Zr, Co, Al, Mn, Ti, Ta, or the like. Moreover, a similar tendency is obtained again in the case of mixing Al in an oxide film of Hf, Zr, Mn, Ti, Ta, or the like.

In the forming process in FIG. 3A, if a voltage higher than necessary is applied to the memory cell MC, the diameter of the filament F to be formed becomes larger, which makes it difficult to oxidize the filament again by oxygen supplied in the reset process and thus the switching operation cannot be performed. The ratio of the number of memory cells capable of performing the switching operation with respect to the number of all the memory cells MC is a switching probability. For increasing the switching probability of the nonvolatile memory device, it is important to control the diameter of the filament F to be formed, specially, in the forming process to the extent that the situation that the variable resistive layer RW cannot become the high resistance state even by reoxidation in the reset process does not occur.

As described above, in the first embodiment, because the element with a high electronegativity is mixed in a metal oxide film forming the variable resistive layer RW, for example, in the forming process, oxygen is difficult to release compared with the case of forming the variable resistive layer RW only with a metal oxide film. Consequently, the diameter of the filament F is suppressed from being increased more than necessary, so that the switching probability can be increased compared with the case of forming the variable resistive layer RW only with a metal oxide film.

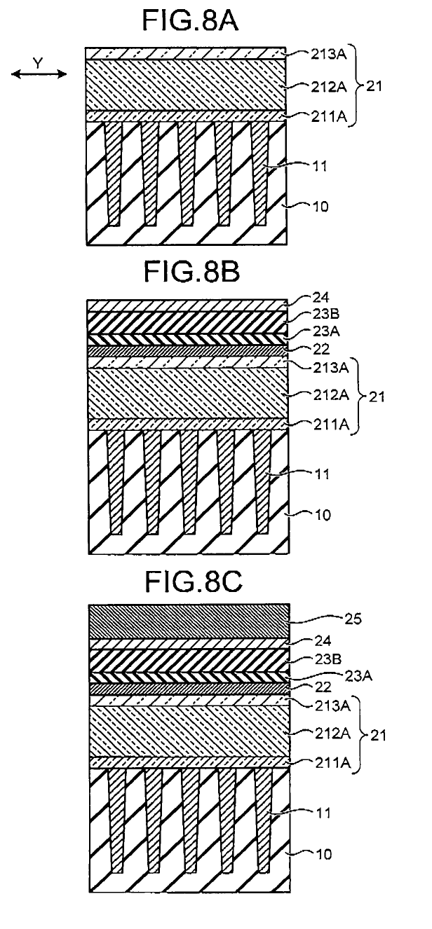

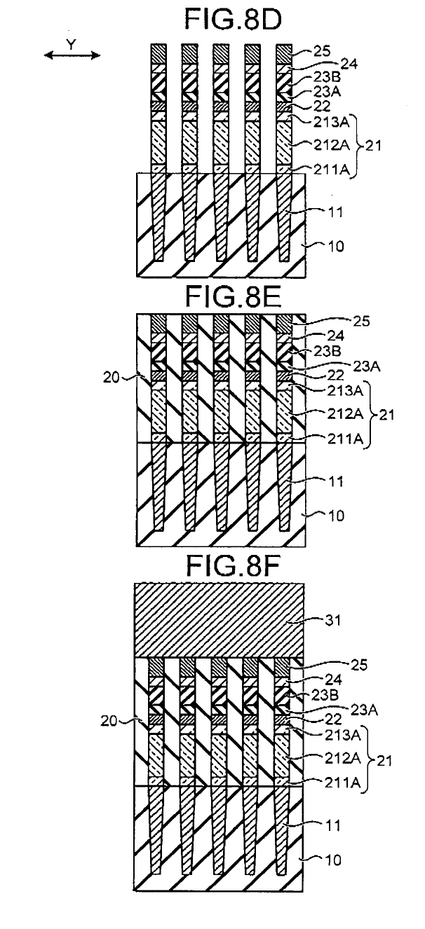

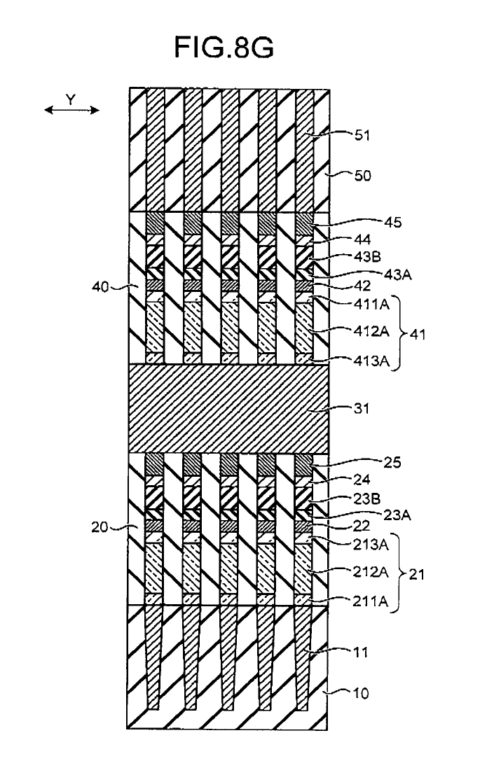

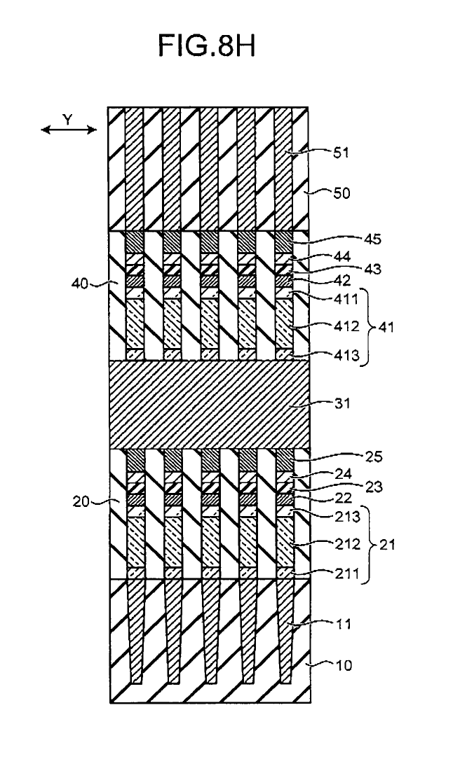

Next, the manufacturing method of the nonvolatile memory device having such a structure is explained. FIG. 8A to FIG. 8H are cross-sectional views schematically illustrating an example of a procedure of the manufacturing method of the nonvolatile memory device in the first embodiment. In this example, explanation is given for the case of forming a plurality of the memory cells MC with reference to the cross section along the bit line BL in FIG. 1 as an example.

First, as shown in FIG. 8A, a first inter-layer dielectric film 10 is formed on a substrate such as a not-shown Si substrate, and first wires 11 (the word lines WL) that extend in the X direction are formed in this first inter-layer dielectric film 10 by a method such as a damascene method. An element such as a CMOS (Complementary Metal-Oxide Semiconductor) transistor is formed in the substrate of the lower layer of the first inter-layer dielectric film 10. Next, on the first inter-layer dielectric film 10 in which the first wires 11 are formed, an N-type amorphous silicon film 211A with the thickness of about 20 nm, an I-type amorphous silicon film 212A with the thickness of about 110 nm, and a P-type amorphous silicon film 213A with the thickness of about 20 nm are deposited in order by a film forming method such as the CVD (Chemical Vapor Deposition) method to form a rectifier layer 21. The N-type amorphous silicon film 211A is obtained by depositing a silicon film while introducing N-type impurities such as P (phosphorus), the I-type amorphous silicon film 212A is obtained by depositing a silicon film in an environment of avoiding introduction of impurities, and the P-type amorphous silicon film 213A is obtained by depositing a silicon film while introducing P-type impurities such as B (boron).

Thereafter, as shown in FIG. 8B, a lower portion electrode layer 22 with the thickness of about 5 nm is formed on the rectifier layer 21 by a method such as the sputtering method and the CVD method. Next, a diffusion source film 23A with the thickness of about 2 nm formed of a silicon oxide film and a metal oxide film 238 with the thickness of about B nm formed of, for example an HfO film are stacked on the lower portion electrode layer 22 by a method such as the sputtering method and the CVD method. The diffusion source film 23A is formed of a film including an element whose electronegativity is higher than a metal element forming the metal oxide film 23B, and an alumina film or the like can be used other than the silicon oxide film. Moreover, an upper portion electrode layer 24 with the thickness of 5 nm formed of a titanium nitride film is formed on the metal oxide film 23B by a film forming method such as the sputtering method and the CVD method.

Thereafter, as shown in FIG. 8C, a cap film 25 is formed on the upper portion electrode layer 24 by a film forming method such as the sputtering method. As this cap film 25, for example, a W film can be used. The cap film 25 is a film formed of a conductive material introduced in view of the process for connecting the memory cell MC with a second wire 31 of the upper layer and causing it to function as a stopper film in etching.

Next, not-shown photo resist is applied to the cap film 25, which is patterned to be a desired pattern by a lithography technique to form a mask. Then, as shown in FIG. 8D, the cap film 25, the upper portion electrode layer 24, the metal oxide film 23B, the diffusion source film 23A, the lower portion electrode layer 22, and the rectifier layer 21 are processed by the anisotropic etching such as the RIE (Reactive Ion Etching) method with the not-shown photo resist as a mask to form a memory cell array pattern in which columnar memory cell patterns are two-dimensionally arranged. At this time, each columnar memory cell pattern has a structure in which the rectifier layer 21, the lower portion electrode layer 22, the diffusion source film 23A, the metal oxide film 23B, the upper portion electrode layer 24, and the cap film 25 are stacked in order on the first wire 11.

Thereafter, as shown in FIG. 8E, a gap between the memory cell patterns processed into a columnar shape is filled by depositing a second inter-layer dielectric film 20 to be higher than the upper surface of the cap film 25. In this example, an HDP-USG (High density Plasma-Undoped Silicate Glasses) film formed by, for example, the plasma CVD method is deposited as the second inter-layer dielectric film 20. Then, the upper surface of the second inter-layer dielectric film 20 is flattened by a method such as the CMP (Chemical Mechanical Polishing) method until the upper surface of the cap film 25 is exposed. If the flattening is performed without forming the cap film 25, the upper portion electrode layer 24 and the metal oxide film 23B may be subjected to the CMP process along with retraction of the upper surface of the second inter-layer dielectric film 20. If the upper portion electrode layer 24 and the metal oxide film 23B are subjected to the CMP process, the characteristics of the memory cell may change, which is not preferable. Thus, the cap film 25 is formed on the upper portion electrode layer 24 to prevent the upper portion electrode layer 24 from being subjected to the CMP process, thereby preventing degradation of the characteristics.

Next, not-shown a third inter-layer dielectric film is formed on the cap film 25 and the second inter-layer dielectric film 20, and the upper surface thereof is flattened. Thereafter, a resist material is applied to the third inter-layer dielectric film and a mask is formed to have an opening shape corresponding to the second wires 31 (the bit lines BL) on the formation position of the memory cell patterns by the lithography technique. Moreover, as shown in FIG. 8F, the third inter-layer dielectric film is etched by the RIE method or the like by using this mask until the cap film 25 is exposed to form trenches for the second wire formation, and a metal material such as W is embedded in the trenches to form the second wires 31 (the bit lines BL) that extend in the Y direction. Consequently, a first memory cell array is formed.

Thereafter, as shown in FIG. 8G, it is applicable to stack a plurality of structures in each of which memory cells are sandwiched between upper and lower wires that are orthogonal to each other by repeating the above process the required number of times. FIG. 8G illustrates the case of forming two layers. In the second memory layer, a rectifier layer 41, a lower portion electrode layer 42, a diffusion source film 43A, a metal oxide film 43B, an upper portion electrode layer 44, and a cap film 45 are processed into columnar memory cell patterns on the second wire 31 (the bit line BL) and a fourth inter-layer dielectric film 40 is embedded between the memory cell patterns. Moreover, a fifth inter-layer dielectric film 50 is formed on the fourth inter-layer dielectric film 40 and third wires 51 (the word lines WL) are formed by being embedded in the fifth inter-layer dielectric film 50 to extend in the X direction by the damascene method.

In the case of the second memory layer, the upper layer is the third wires 51 (the word lines WL), so that the rectifier layer 41 is formed to cause current to flow from the bit line BL to the direction of the word line WL. In other words, the rectifier layer 41 has a structure in which a P-type amorphous silicon film 413A, an I-type amorphous silicon film 412A, and an N-type amorphous silicon film 411A are stacked in order on the second wire 31. Consequently, the second memory cell array is formed. Moreover, in the case of forming a multilayered structure, it is only necessary to form such that an odd memory cell array has a structure similar to the above first memory cell array and an even memory cell array has a structure similar to the above second memory cell array by a procedure similar to the above procedure. In this manner, the structure is obtained in which the bit lines or the word lines are shared between adjacent upper and lower memory cell arrays.

Then, as shown in FIG. 8H, the heat treatment is performed at a temperature of, for example, about 700° C. to 800° C. to crystallize and activate the rectifier layers 21 and 41 formed of the amorphous silicon films 211A to 213A and 411A to 413A, thereby forming N-type polycrystalline silicon films 211 and 411, I-type polycrystalline silicon films 212 and 412, and P-type polycrystalline silicon films 213 and 413. With this heat treatment, diffusion occurs between the diffusion source film 23A and the metal oxide film 23B and between the diffusion source film 43A and the metal oxide film 43B, thereby forming variable resistive layers 23 and 43 in which Si whose electronegativity is higher than Hf is mixed in the metal oxide films 23B and 43B, respectively. The heat treatment time is controlled to the time in which the element with a high electronegativity becomes uniform in the variable resistive layers 23 and 43. Consequently, the nonvolatile memory device is obtained.

In the above explanation, the case is illustrated in which the rectifier layers 21 and 41 and the variable resistive layers 23 and 43 are stacked in this order on the wires 11 and 31, respectively, however, the variable resistive layers 23 and 43 and the rectifier layers 21 and 41 can be stacked in this order on the wires 11 and 31, respectively. Moreover, in the above explanation, as a method of forming the variable resistive layer, the metal oxide films 23B and 43B are formed after forming the diffusion source films 23A and 43A beforehand, however, the forming order can be opposite. Furthermore, the case is illustrated in which a semiconductor layer having a PIN junction structure is used as the rectifier layer, however, a diode having a PN junction structure, a Schottky junction structure, or the like can be used, or an MIM (Metal-Insulator-Metal) structure, an SIS (Silicon-Insulator-Silicon) structure, or the like can be used.

Moreover, in the above explanation, the case of a unipolar-type variable resistance memory is explained as an example, however, the first embodiment can be applied also to the case of a bipolar-type variable resistance memory.

In the first embodiment, the variable resistive layer RW is formed of a film obtained by uniformly mixing an element whose electronegativity is higher than a metal element forming a metal oxide film in the metal oxide film. Consequently, the set voltage rises and the reset voltage is lowered, and therefore the voltage margin that is the difference between both voltages increases, compared with the case of a metal oxide film including no element with a high electronegativity due to the effect of the element with a high electronegativity. As a result, an effect is obtained in that generation of the erroneous setting problem as shown in FIG. 5 can be suppressed.

Moreover, because the voltage margin increases, the ratio (Rₒₙ/R_{off} ratio) of the resistance value between the low resistance state and the high resistance state in the read voltage becomes larger compared with the case of a metal oxide film including no element with a high electronegativity as shown in FIG. 4A and FIG. 4B, whereby an effect is obtain in that a read error of the resistance value information can be suppressed.

Furthermore, oxygen is not easily released by uniformly including the element with a high electronegativity in a metal oxide film, so that an effect is obtained in that data retention characteristics are improved compared with the case of forming the variable resistive layer only with a metal oxide film and the nonvolatile memory device becomes susceptible to a read disturb.

### Second Embodiment

In the first embodiment, the case is explained in which the variable resistive layer is a film obtained by uniformly mixing an element whose electronegativity is higher than a metal element forming a metal oxide film in the metal oxide film. In the second embodiment, the case is explained in which the variable resistive layer is a film obtained by causing an element whose electronegativity is higher than a metal element forming a metal oxide film to be present in the metal oxide film in a concentration gradient.

The variable resistance memory in the second embodiment also has a structure same as that in FIG. 2 in the first embodiment. When the variable resistance memory has a unipolar-type structure, the variable resistive layer RW is formed of a thin film in which the concentration of an element whose electronegativity is higher than a metal element forming a metal oxide film is controlled to become smaller from the cathode side (the lower portion electrode layer BE side) to the anode side (the upper portion electrode layer TE side) in the metal oxide film. In other words, the element with a high electronegativity has a concentration gradient in the variable resistive layer RW along a direction of current flowing in the variable resistive layer RW. In the variable resistive element VR, an electrode on the upstream side is an anode and an electrode on the downstream side is a cathode with reference to a direction in which current flows. Therefore, in the example in FIG. 2, the lower portion electrode layer BE functions as a cathode and the upper portion electrode layer TE functions as an anode.

In this manner, the concentration of the element with a high electronegativity is higher on the cathode side, so that oxygen supplied from the cathode side is captured by the element with a high electronegativity. Specially, because the concentration of the element with a high electronegativity is high on the cathode side, oxygen supplied from the cathode side is efficiently captured and it becomes difficult for oxygen to diffuse to the upper portion electrode layer TE side in the variable resistive layer RW, so that the filament F is prevented from being oxidized.

In other words, an effect is obtained that the anode side is prevented from being affected by the effect of oxygen supplied from the cathode side more efficiently and thus the switching controllability on the anode side is improved. Moreover, although the concentration of the element with a high electronegativity is lower on the anode side than the cathode side, the effect is obtained that the voltage margin ΔVₘ is increased by the element with a high electronegativity as described in the first embodiment.

When the variable resistance memory has a bipolar-type structure, the concentration of the element with a high electronegativity in the variable resistive layer RW can be set to become smaller from the cathode side to the anode side or become smaller from the anode side to the cathode side.

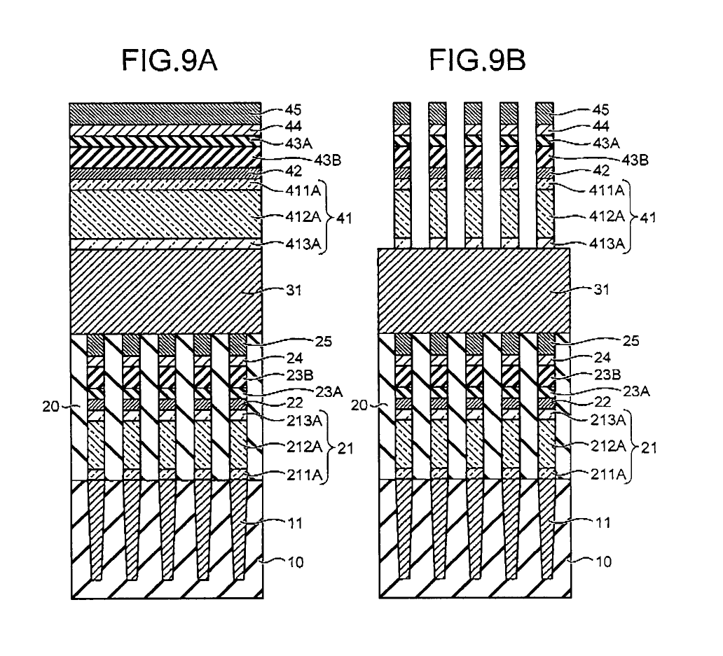

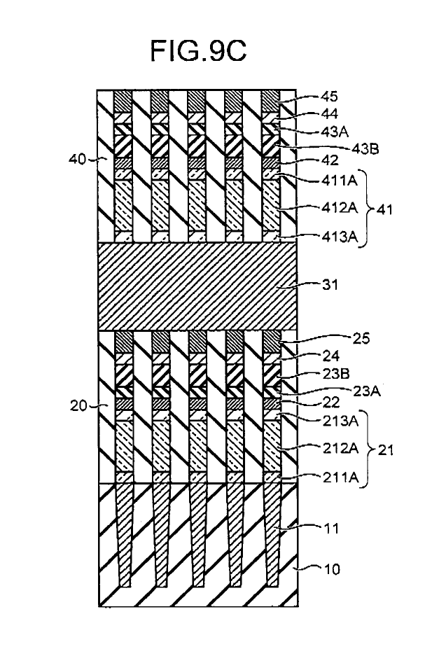

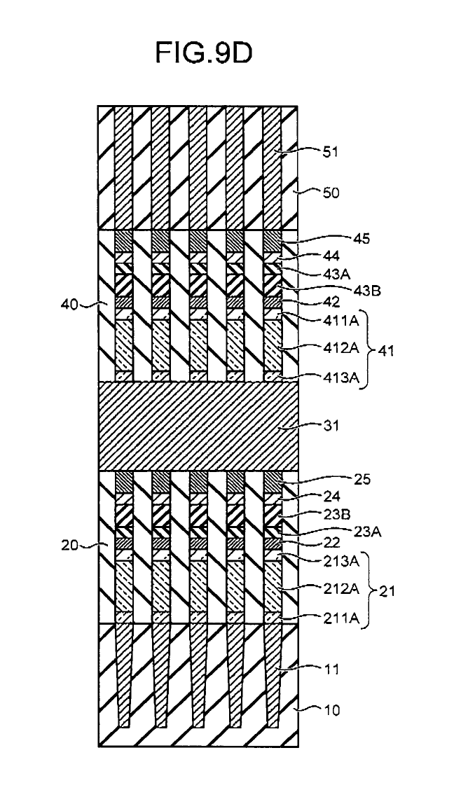

Next, the manufacturing method of the nonvolatile memory device having such a structure is explained. FIG. 9A to FIG. 9D are cross-sectional views schematically illustrating an example of a procedure of the manufacturing method of the nonvolatile memory device in the second embodiment. The first memory cell array is formed by a procedure similar to FIG. 8A to FIG. 8F in the first embodiment. The rectifier layer 21 has a structure in which the N-type amorphous silicon film 211A is formed on the side of the first wires 11 to cause current to flow from the bit line (the second wire 31) to the word line (the first wire 11), so that the lower portion electrode layer 22 is formed on the P-type amorphous silicon film 213A. In other words, the lower portion electrode layer 22 becomes a cathode. Therefore, the diffusion source film 23A is formed on the lower portion electrode layer 22.

Next, as shown in FIG. 9A, the rectifier layer 41, the lower portion electrode layer 42, the metal oxide film 43B, the diffusion source film 43A, the upper portion electrode layer 44, and the cap film 45 are formed on the third inter-layer dielectric film in which the second wires 31 are embedded by a method such as the sputtering method and the CVD method.

In the case of the second memory cell array to be formed, the word lines (not-shown third wires) are formed on the upper layer, so that the rectifier layer 41 is formed to cause current to flow in a direction different from the direction of current in the first memory cell array for flowing current from the bit line to the word line. In other words, the rectifier layer 41 has a structure in which the P-type amorphous silicon film 413A, the I-type amorphous silicon film 412A, and the N-type amorphous silicon film 411A are stacked in order on the third inter-layer dielectric film in which the second wires 31 are embedded.

Moreover, because the direction in which current flows in the rectifier layer 41 is different from the first memory cell array, the lower portion electrode layer 42 in the second layer becomes an anode and the upper portion electrode layer 44 becomes a cathode. Consequently, the diffusion source film 43A is formed on the side of the upper portion electrode layer 44 as a cathode different from the first memory cell array. Such a manufacturing method is applied to the case of a unipolar-type nonvolatile memory device, and in the case of a bipolar-type nonvolatile memory device, the diffusion source films 23A and 43A can be provided on the cathode side or on the anode side.

Thereafter, not-show photo resist is applied to the cap film 45, which is patterned to be a desired pattern by the lithography technique to form a mask. Then, as shown in FIG. 9B, the cap film 45, the upper portion electrode layer 44, the diffusion source film 43A, the metal oxide film 43B, the lower portion electrode layer 42, and the rectifier layer 41 are processed by the anisotropic etching such as the RIE method with the not-shown photo resist as a mask to form a memory cell array pattern in which columnar memory cell patterns are two-dimensionally arranged. At this time, each columnar memory cell pattern has a structure in which the rectifier layer 41, the lower portion electrode layer 42, the metal oxide film 43B, the diffusion source film 43A, the upper portion electrode layer 44, and the cap film 45 are stacked in order on the third wire 31.

Thereafter, as shown in FIG. 9C, a gap between the memory cell patterns processed into a columnar shape is filled by depositing the fourth inter-layer dielectric film 40 to be higher than the upper surface of the cap film 45. Then, the upper surface of the fourth inter-layer dielectric film 40 is flattened by a method such as the CMP method until the upper surface of the cap film 45 is exposed.

Next, a not-shown fifth inter-layer dielectric film is formed on the cap film 45 and the fourth inter-layer dielectric film 40, and the upper surface thereof is flattened. Thereafter, photo resist is applied to the fifth inter-layer dielectric film and a mask is formed to have an opening shape corresponding to the third wires (the word lines WL) on the formation position of the memory cell patterns by the lithography technique. Thereafter, as shown in FIG. 9D, the fifth inter-layer dielectric film is etched by the RIE method or the like by using this mask until the cap film 45 is exposed to form trenches for the third wire formation, and a metal material such as W is embedded in the trenches to form the third wires 51 (the word lines WL) that extend in the X direction. Consequently, a second memory cell array is formed.

Thereafter, it is applicable to stack a plurality of structures in each of which memory cells are sandwiched between upper and lower wires that are orthogonal to each other by repeating the above process the required number of times. In this case, it is only necessary to form such that an odd memory cell array has a structure similar to the above first memory cell array and an even memory cell array has a structure similar to the above second memory cell array. In this manner, the structure is obtained in which the bit lines or the word lines are shared between adjacent upper and lower memory cell arrays. This example illustrates the case of stacking two layers of the memory cell arrays.

Then, as shown in FIG. 8H in the first embodiment, the heat treatment is performed at a temperature of, for example, about 700° C. to 800° C. to crystallize and activate the rectifier layers 21 and 41 formed of the amorphous silicon films 211A to 213A and 411A to 413A, thereby forming the N-type polycrystalline silicon films 211 and 411, the I-type polycrystalline silicon films 212 and 412, and the P-type polycrystalline silicon films 213 and 413. With this heat treatment, diffusion occurs between the diffusion source film 23A and the metal oxide film 23B and between the diffusion source film 43A and the metal oxide film 43B. The heat treatment time at this time is shortened compared with the case of the first embodiment, whereby the variable resistive layers 23 and 43 are formed, in which the concentration of Si whose electronegativity is higher than Hf becomes smaller from the cathode (the lower portion electrode layer 22 and the upper portion electrode layer 44) to the anode (the upper portion electrode layer 24 and the lower portion electrode layer 42). Consequently, the nonvolatile memory device is obtained.

In the above explanation, the case is illustrated in which the rectifier layers 21 and 41 and the variable resistive layers 23 and 43 are stacked in this order on the wires 11 and 31, respectively, however, the variable resistive layers 23 and 43 and the rectifier layers 21 and 41 can be stacked in this order on the wires 11 and 31, respectively. Moreover, in the above explanation, the case is illustrated in which a semiconductor layer having a PIN junction structure is used as the rectifier layer, however, a diode having a PN junction structure, a Schottky junction structure, or the like can be used, or an MIM structure, an SIS structure, or the like can be used.

Moreover, as a method of forming the variable resistive layers 23 and 43, in addition to the case of forming the diffusion source films 23A and 43A on the cathode side and forming the metal oxide films 23B and 43B on the anode side as above, it is possible to form the concentration gradient in the variable resistive layers 23 and 43, in which the element with a high electronegativity gradually decreases from the cathode to the anode by stacking the diffusion source films 23A and 43A and the metal oxide films 23B and 43B alternately with a few nm thickness on the lower portion electrode layers 22 and 42, respectively, by the ALD (Atomic Layer Deposition) method and performing the heat treatment.

Moreover, the manufacturing method of the nonvolatile memory device is not limited to the above. For example, after forming the first wire layer, the first rectifier layer, the first lower portion electrode layer, the first variable resistive layer, the first upper portion electrode layer, and the first cap film, the portion from the first cap film to the first wire layer is processed into line and space patterns that extend in the first direction. Next, the inter-layer dielectric film is embedded between the processed structures, the second wire layer, the second rectifier layer, the second lower portion electrode layer, the second variable resistive layer, the second upper portion electrode layer, and the second cap film are formed on the inter-layer dielectric film in the state where the first cap film is exposed, the portion from the second cap film to the first rectifier layer is processed into line and space patterns that extend in the second direction orthogonal to the first direction, and the inter-layer dielectric film is embedded between the processed structures. Such process is performed a plurality of times, and finally, the wire layer is formed on the inter-layer dielectric film from which the cap film of the lower layer is exposed, the portion up to the rectifier layer formed on the wire layer immediately thereunder is processed into the line and space shape in the direction different from the line and space patterns formed in the lower layer, and the inter-layer dielectric film is embedded between the processed structures. Consequently, it is possible to obtain the nonvolatile memory device having a structure in which the variable resistance memory cells in each of which the rectifier layer, the lower portion electrode layer, the variable resistive layer, the upper portion electrode layer, and the cap film are processed into a columnar shape are sandwiched at the intersection positions of the upper and lower wire layers that are orthogonal to each other.

In the second embodiment also, an effect similar to the first embodiment can be obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile memory device comprising a nonvolatile memory layer, wherein
the nonvolatile memory layer is formed of a metal oxide film that includes an element with a higher electronegativity compared with a metal element forming the metal oxide film in the metal oxide film at a concentration of 25 at % or less.

2. The nonvolatile memory device according to claim 1, wherein the element with a higher electronegativity is included in the metal oxide film at a concentration of 3 at % or more and 5 at % or less.

3. The nonvolatile memory device according to claim 1, wherein the element with a high electronegativity is included uniformly in the metal oxide film.

4. The nonvolatile memory device according to claim 1, wherein the element with a high electronegativity is included in the metal oxide film to have a concentration gradient along a thickness direction of the nonvolatile memory layer.

5. The nonvolatile memory device according to claim 1, further comprising a rectifier layer that is coupled with the nonvolatile memory layer in series.

6. The nonvolatile memory device according to claim 5, wherein the rectifier element is any of a Schottky diode, a PN junction diode, a PIN diode, a Metal-Insulator-Metal structure, and a Silicon-Insulator-Silicon structure.

7. The nonvolatile memory device according to claim 4, further comprising a rectifier layer that is connected to the nonvolatile memory layer in series, wherein
the nonvolatile memory layer is arranged so that a concentration of the element with a high electronegativity becomes higher from an anode to a cathode defined by the rectifier layer.

8. The nonvolatile memory device according to claim 7, wherein the rectifier element is any of a Schottky diode, a PN junction diode, a PIN diode, a Metal-Insulator-Metal structure, and a Silicon-Insulator-Silicon structure.

9. The nonvolatile memory device according to claim 1, wherein the metal oxide film is an oxide film including at least one metal element selected from the group consisting of Hf, Zr, Co, Al, Mn, Ti, and Ta.

10. The nonvolatile memory device according to claim 1, wherein the element with a high electronegativity is at least one of Si and Al.

11. The nonvolatile memory device according to claim 1, further comprising an electrode layer that is arranged to be in contact with the nonvolatile memory layer.

12. The nonvolatile memory device according to claim 11, wherein the electrode layer is formed of at least one metal material selected from the group consisting of Pt, Au, Ag, Ru, Ir, Co, Al, Ti, W, Mo, and Ta, or nitride of at least one metal material selected from the group consisting of Ti, W, Mo, and Ta.

13. The nonvolatile memory device according to claim 1, wherein the nonvolatile memory layer is arranged to be sandwiched between a plurality of first wires that extend in a first direction and a plurality of second wires that extend in a second direction at a height different from the first wires at each intersection position of the first wires and the second wires.
